(19) United States
(12) Patent Application Publication
(10) Pub. No.: US 2026/0100700 A1
(43) Pub. Date: Apr. 9, 2026

(54) DUTY CYCLE CORRECTION CIRCUIT AND METHOD FOR OPERATING THE SAME

(71) Applicant: TAIWAN SEMICONDUCTOR MANUFACTURING COMPANY LTD., HSINCHU (TW)

(72) Inventor: CHANG-YI LI, YUNLIN COUNTY (TW)

(21) Appl. No.: 18/910,043

(22) Filed: Oct. 9, 2024

(51) Int. Cl. H03K 5/156; H03K 3/037; H03K 5/00; H03K 5/131; H03K 5/14

(52) U.S. Cl. CPC H03K 5/1565; H03K 3/0372; H03K 5/131; H03K 5/14; H03K 2005/00058

(57) ABSTRACT

The present disclosure provides an integrated circuit, which includes a master circuit and a slave circuit. The master circuit is configured to receive an input clock signal and generate an intermediate clock signal based on a first half and a second half of a first trimming code. The slave circuit is electrically connected to the master circuit and is configured to receive the intermediate clock signal and generate an output clock signal from the intermediate clock signal based on a first half and a second half of a second trimming code. The first trimming code is complementary to the second trimming code.

### BACKGROUND

Digitally controlled delay lines (DCDLs) are well-established components in the field of signal processing and telecommunications. DCDLs are utilized to delay the transmission of digital signals by a precise amount of time, which is important in various applications such as synchronization, phase alignment, and timing adjustments. The principle of DCDLs involves the use of digital circuits to control the delay period, offering high accuracy and flexibility compared to their analog counterparts. Over the years, advancements in semiconductor technology have enabled the development of more compact and efficient digitally controlled delay lines, integrating them into complex systems such as digital communication networks, radar systems, and audio processing equipment. The integration of these delay lines into modern electronic devices has significantly enhanced their performance, reliability, and functionality, making them indispensable in contemporary digital signal processing applications.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a block diagram of a duty cycle correction circuit in accordance with some embodiments of the present disclosure.

FIG. 2A is a simplified schematic diagram of a duty cycle correction circuit in accordance with some embodiments of the present disclosure.

FIG. 2B is a schematic diagram of a duty cycle correction circuit in FIG. 2A.

FIG. 2C is a schematic diagram of a duty cycle correction circuit in accordance with some embodiments of the present disclosure.

FIG. 3 is a diagram illustrating the relationship between the trimming code and the duty cycle of the output clock signal in different process corner cases in accordance with the embodiment of FIGS. 2A-2B.

FIG. 4 is a schematic diagram of a duty cycle correction circuit in accordance with some embodiments of the present disclosure.

FIG. 5 is a block diagram of a duty cycle correction circuit in accordance with some embodiments of the present disclosure.

FIG. 6A is a schematic diagram of a duty cycle correction circuit in accordance with some embodiments of the present disclosure.

FIG. 6B is a schematic diagram of a duty cycle correction circuit in accordance with some embodiments of the present disclosure.

FIG. 7 is a schematic diagram of digitally controlled delay line (DCDL) circuit in accordance with some embodiments of the present disclosure.

FIG. 8 is a diagram illustrating the relationship between a delay time of the output clock signal with respect to the trimming code (e.g., “Code”) in different corner cases in accordance with the embodiment of FIG. 7.

FIG. 9 is a flowchart of a method for operating a duty cycle correction circuit in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

In some embodiments, a duty cycle correction circuit with a balanced master-slave circuit architecture is provided. The master circuit can adjust the duty cycle of an input clock signal based on a first half and a second half of a first trimming code to generate an intermediate clock signal, and the slave circuit can adjust the duty cycle of the intermediate clock signal based on a first half and a second half of a second trimming code complementary to the first trimming code to generate an output clock signal, which can have a duty cycle of substantially 50%.

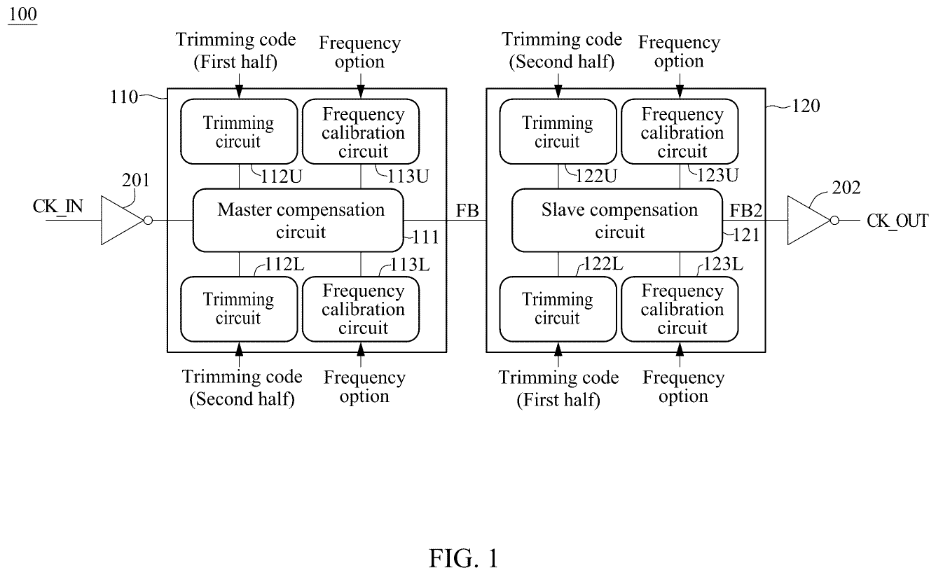

FIG. 1 is a block diagram of a duty cycle correction circuit in accordance with some embodiments of the present disclosure.

In some embodiments, the duty cycle correction circuit 100 may be implemented in a circuit that communicates with a high-speed circuit. An example circuit includes, but is not limited to, a de-skew circuit, a memory input/output interface, and/or a data converter circuit. An example high-speed circuit includes, but is not limited to, a processing device, a memory input/output interface, and a high-frequency data converter. The example processing device includes, but is not limited to, a central processing unit, a microprocessor, and a digital signal processor.

In some embodiments, the duty cycle correction circuit 100 is a digital duty cycle corrector (DDCC) circuit configured to adjust the duty cycle of an input clock signal CK_IN to generate an output clock signal CK_OUT within a predefined duty cycle range, such as between 40% and 60%. The duty cycle correction circuit 100 includes a master circuit 110 and a slave circuit 120, as depicted in FIG. 1. The master circuit 110 is configured to operate in conjunction with the slave circuit 120 to achieve PN mismatch compensation using a trimming code (i.e., also referred to as “trim code” in short) and a frequency option through respective feedback paths, allowing the output clock signal to operate with a target duty cycle.

In some embodiments, the master circuit 110 includes a master compensation circuit 111, trimming circuits 112U and 112L, and frequency calibration circuits 113U and 113L. The master compensation circuit 111 may be configured to generate an intermediate clock signal FB, which serves as a feedback signal used by the master compensation circuit 111, from the input clock signal CK_IN through inverter 201. In some embodiments, the trimming circuit 112U and the frequency calibration circuit 113U can be used as voltage pull-up circuits, and the voltage pull-up duration of the intermediate clock signal FB can be determined by the trimming circuit 112U and the frequency calibration circuit 113U. The trimming circuit 112L and the frequency calibration circuit 113L can be used as voltage pull-down circuits, and the voltage pull-down duration of the intermediate clock signal FB can be determined by the trimming circuit 112L and the frequency calibration circuit 113L. In some embodiments, P-type transistors are employed within the voltage pull-up circuits, while N-type transistors are employed within the voltage pull-down circuits.

In some embodiments, the duty cycle of the output clock signal CK_OUT can be adjusted by a trimming code EN and its inverse trimming code ENB. For example, the trimming codes EN and ENB each can be divided into a first half and a second half. For ease of description, the trimming codes EN and ENB are 64 bits, which can be expressed as EN[0:63] and ENB[0:63], respectively. In some embodiments, the first half of the trimming code EN may refer to the least significant half or the lower half (e.g., EN[0:31]), while the second half of the trimming code EN may refer to the most significant half or the upper half (e.g., EN[32:63]). Similarly, the first half of the trimming code ENB may refer to the least significant half (e.g., ENB[0:31]), while the second half of the trimming code ENB may refer to the most significant half (e.g., ENB[32:63]). In some other embodiments, the first half of the trimming code EN may refer to the most significant half or the upper half (e.g., EN[32:63]), while the second half of the trimming code EN may refer to the least significant half or the lower half (e.g., EN[0:31]). Similarly, the first half of the trimming code ENB may refer to the most significant half (e.g., ENB[32:63]), while the second half of the trimming code ENB may refer to the least significant half (e.g., ENB[0:31]).

In still some other embodiments, the first half of the trimming code EN may refer to even number indexed bits (e.g., EN[0], EN[2], . . . , EN[62]), while the second half of the trimming code EN may refer to the odd number indexed bits (e.g., EN[1], EN[3], . . . , EN[63]). Similarly, the first half of the trimming code ENB may refer to even number indexed bits (e.g., ENB[0], ENB[2], . . . , ENB[62]), while the second half of the trimming code ENB may refer to the odd number indexed bits (e.g., ENB[1], ENB[3], . . . , ENB[63]). It should be noted that there may be other ways to divide the bits within the trimming codes EN and ENB into a first half and a second half, and the present disclosure is not limited to the aforementioned embodiments. For purposes of description, the first half and second half of the trimming code EN refer to the upper half and lower half of the trimming code EN, respectively.

In some embodiments, regarding the master circuit 110, the first half of the trimming code EN (e.g., EN[0:31]) is sent to the trimming circuit 112U (e.g., voltage pull-up circuit), while the second half of the trimming code EN is sent to the trimming circuit 112L (e.g., voltage pull-down circuit). Regarding the slave circuit 120, the second half of the trimming code ENB (e.g., ENB[32:63]) is sent to the trimming circuit 122U (e.g., voltage pull-up circuit), while the first half of the trimming code ENB (e.g., ENB[0:31]) is sent to the trimming circuit 112L (e.g., voltage pull-down circuit).

In some embodiments, the frequency of the output clock signal CK_OUT can be adjusted by a frequency option signal FREQ and its inverse signal FREQ_B, For ease of description, the frequency option signals FREQ and FREQ_B are 2 bits, which can be expressed as FREQ[0:1] and its inverse signal FREQ[0:1], respectively. For the master circuit 110, the frequency option signal FREQ is sent to the frequency calibration circuit 113U (e.g., a voltage pull-up circuit), while the frequency option signal FREQ_B is set to the frequency calibration circuit 113L (e.g., a voltage pull-down circuit). For the slave circuit 110, the frequency option signal is sent to the frequency calibration circuit 123U (e.g., a voltage pull-up circuit), while the frequency option signal FREQ_B is set to the frequency calibration circuit 123L (e.g., a voltage pull-down circuit).

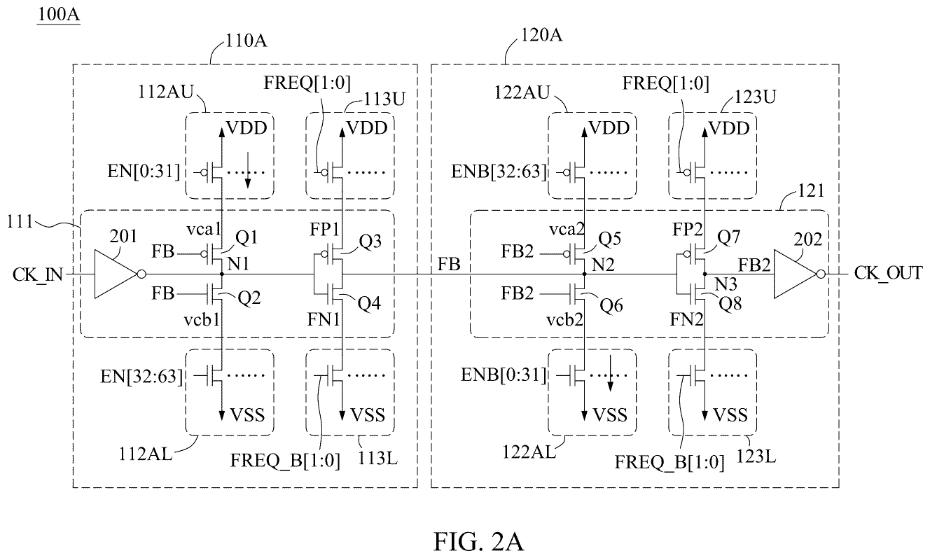

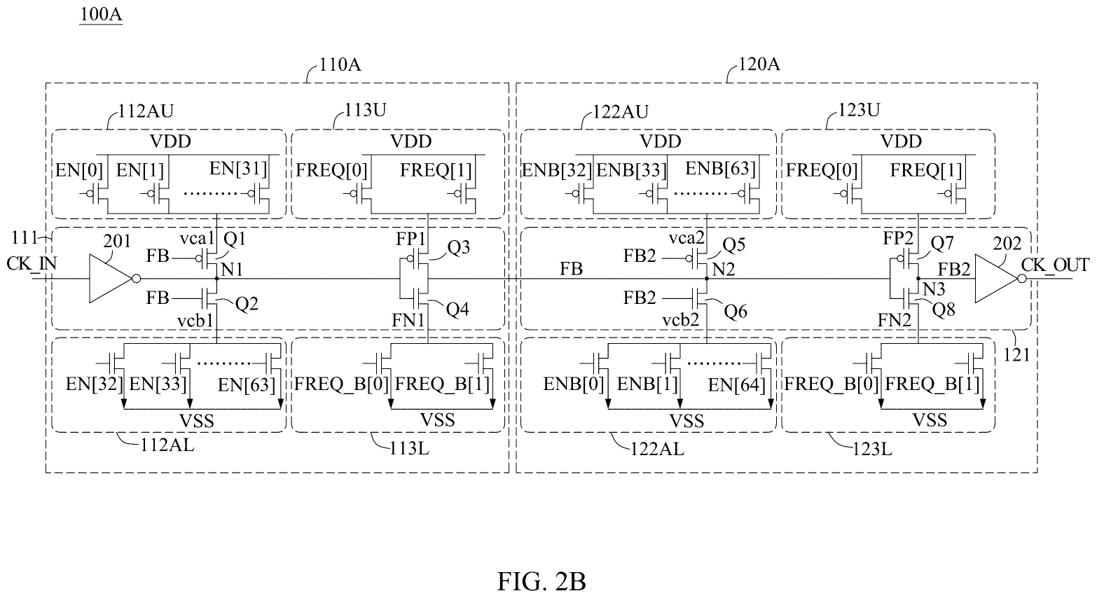

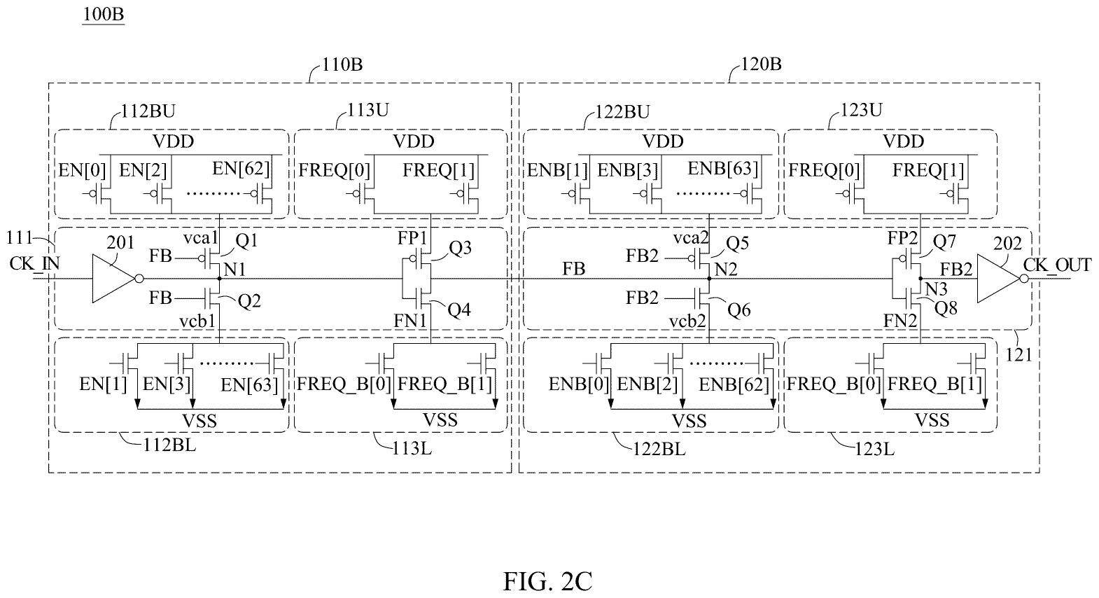

FIG. 2A is a simplified schematic diagram of a duty cycle correction circuit in accordance with some embodiments of the present disclosure. FIG. 2B is a schematic diagram of a duty cycle correction circuit in FIG. 2A.

In some embodiments, the duty cycle correction circuit 100 shown in FIG. 1 can be implemented by the duty cycle correction circuit 100A shown in FIG. 2A. For example, the duty cycle correction circuit 100A includes the master circuit 110A and slave circuit 120A, as depicted in FIG. 2A. The master circuit 110A includes a master compensation circuit 111, trimming circuits 112AU and 112AL, and frequency calibration circuits 113U and 113L. In some embodiments, the master compensation circuit 111 includes inverter 201 and transistors Q1 to Q4. The input clock signal CK_IN is coupled to node N1 through inverter 201. Transistors Q1 and Q2 form a first driver, while transistors Q3 and Q4 form a second driver. The intermediate output signal FB generated by the second driver is fed back to gate terminals of transistors Q1 and Q2. It should be noted that inverter 201 is included in the master compensation circuit 111 for purposes of description. Alternatively, inverter 201 can be disposed outside the master circuit 110A, which is similar to the arrangement shown in FIG. 1.

In some embodiments, the trimming circuit 112AU is coupled between a power supply voltage VDD and transistor Q1. The trimming circuit 112AU includes a plurality of P-type transistors (e.g., P-type switches) arranged in parallel, each receiving a respective bit of the first half of the trimming code EN (e.g., EN[0:31]). In addition, the trimming circuit 112AU provides a voltage vca1 at the source terminal of transistor Q1. The trimming circuit 112AL is coupled between a reference voltage VSS and transistor Q2. The trimming circuit 112AL includes a plurality of N-type transistors (e.g., N-type switches) arranged in parallel, each receiving a respective bit of the second half of the trimming code EN (e.g., EN[32:63]). In addition, the trimming circuit 112AL provides a voltage vcb1 at the source terminal of transistor Q2. The voltage signal generated at node N1 is sent to the inverter formed by transistors Q3 and Q4. Accordingly, the first half and second half of the trimming code EN[0:63] are used to turn on P-type transistors and N-type transistors within the trimming circuits 112AU and 112AL, respectively.

In some embodiments, the frequency calibration circuit 113U is coupled between the power supply voltage VDD and transistor Q3. The frequency calibration circuit 113U includes a plurality of P-type transistors arranged in parallel, each receiving a respective bit of the frequency option signal FREQ[0:1]. In addition, the frequency calibration circuit 113U provides a voltage FP1 at the source terminal of transistor Q3. The frequency calibration circuit 113L is coupled between the reference voltage VSS and transistor Q4. The frequency calibration circuit 113L includes a plurality of N-type transistors arranged in parallel, each receiving a respective bit of the frequency option signal FREQ_B[0:1]. In addition, the frequency calibration circuit 113L provides a voltage FN1 at the source terminal of transistor Q4.

In some embodiments, the intermediate clock signal (or feedback clock signal) FB generated by the master circuit 110A is sent to the slave circuit 120A. The slave circuit 120A includes the slave compensation circuit 121, trimming circuits 122AU and 122AL, and frequency calibration circuits 123U and 123L. In some embodiments, the slave compensation circuit 121 is configured to convert the intermediate clock signal FB to a feedback clock signal FB2. For example, the slave compensation circuit 121 includes transistors Q5 to Q8 and inverter 202. The intermediate clock signal FB is provided to node N2. Transistors Q5 and Q6 form a third driver, while transistors Q7 and Q8 form a fourth driver. The intermediate clock signal generated at the output terminal (e.g., node N3) of the fourth driver (e.g., Q7 and Q8) can be regarded as a feedback clock signal FB2, which is fed back to gate terminals of transistors Q5 and Q6. The feedback clock signal FB2 generated at node N3 may pass through inverter 202 to obtain the output clock signal CK_OUT. It should be noted that inverter 202 is included in the slave compensation circuit 121 for purposes of description. Alternatively, inverter 202 can be disposed outside the slave circuit 120A, which is similar to the arrangement shown in FIG. 1.

In some embodiments, the trimming circuit 122AU is coupled between the power supply voltage VDD and transistor Q5. The trimming circuit 122AU includes a plurality of P-type transistors arranged in parallel, each receiving a respective bit of the second half of the trimming code ENB (e.g., ENB[32:63]). In addition, the trimming circuit 122AU provides a voltage vca2 at the source terminal of transistor Q5. The trimming circuit 122AL is coupled between the reference voltage VSS and transistor Q6. The trimming circuit 122AL includes a plurality of N-type transistors arranged in parallel, each receiving a respective bit of the first half of the trimming code ENB (e.g., ENB[0:31]). In addition, the trimming circuit 122AL provides a voltage vcb2 at the source terminal of transistor Q6. The voltage signal generated at node N2 is sent to the inverter formed by transistors Q7 and Q8. Accordingly, the first half and second half of the trimming code ENB[0:63] are used to turn on P-type transistors and N-type transistors within the trimming circuits 122AU and 122AL, respectively.

In some embodiments, the frequency calibration circuit 123U is coupled between the power supply voltage VDD and transistor Q7. The frequency calibration circuit 123U includes a plurality of P-type transistors arranged in parallel, each receiving a respective bit of the frequency option signal FREQ[0:1]. In addition, the frequency calibration circuit 113U provides a voltage FP2 at the source terminal of transistor Q7. The frequency calibration circuit 123L is coupled between the reference voltage VSS and transistor Q8. The frequency calibration circuit 123L includes a plurality of N-type transistors arranged in parallel, each receiving a respective bit of the frequency option signal FREQ_B[0:1]. In addition, the frequency calibration circuit 113L provides a voltage FN2 at the source terminal of transistor Q8.

In some embodiments, for purposes of description, at least one bit of the trimming code EN[0:63] is 1, indicating that at least one bit of the trimming code ENB[0:63] is 0. Accordingly, at least one P-type transistor within the trimming circuit 112AU of the master circuit 110A is activated by the first half of the trimming code EN (e.g., EN[0:31]), while at least one N-type transistor within the trimming circuit 122AL of the slave circuit 120A is activated by the first half of the trimming code ENB (e.g., ENB[0:31]). Meanwhile, at least one N-type transistor within the trimming circuit 112AL of the master circuit 110A is activated by the second half of the trimming code EN (e.g., EN[32:63]), while at least one P-type transistors within the trimming circuit 122AU of the slave circuit 120A is activated by the second half of the trimming code ENB (e.g., ENB[32:63]). Accordingly, the balance P/N switch function of the duty cycle correction circuit 100A can be expressed using formula (1) as follows.

ΔDuty cycle per code=Δdriving capability of a PMOS+Δdriving capability of a NMOS (1) Specifically, each bit of the trimming code EN or ENB can contribute to the duty cycle of the output clock signal CK_OUT. The master circuit 110A and the slave circuit 120A of the duty cycle correction circuit 100A is designed using a balance or symmetric architecture. When a particular bit within the first half of the trimming code EN (e.g., EN[0:31]) is 0, the particular bit can turn on the respective P-type transistor within the trimming circuit 112AU, making contribution to reduce the voltage pull-up duration of the output clock signal CK_OUT depending on the driving capability of the respective P-type transistor. Meanwhile, the particular bit within the first half of the trimming code ENB (e.g., ENB[0:31] is 1, the particular bit can turn on the respective N-type transistor within the trimming circuit 122AL, making contribution to reduce the voltage pull-down duration of the output clock signal CK_OUT, depending on the driving capability of the respective N-type transistor. In other words, the duty cycle of the output clock signal CK_OUT (i.e., ΔDuty cycle) affected by each bit of the trimming code EN or ENB can be expressed by the summation of the driving capability of one P-type transistor and the driving capability of one N-type transistor. It should be noted that the driving capabilities of P-type transistors and N-type transistor can vary due to variations of the fabricating process of the duty cycle correction circuit 100A, indicating that the driving capability of a P-type transistor can differ from that of an N-type transistor. With the balanced circuit design of the duty cycle correction circuit 100A, even if the driving capability of P-type transistors differ from that of N-type transistors within the duty cycle correction circuit 100A, the duty cycle correction circuit 100A can still balance the duty cycle of the output clock signal CK_OUT at substantially 50%. Furthermore, the layout area of the duty cycle correction circuit 100A can be reduced with the balanced circuit design.

In some embodiments, the frequency of the output clock signal CK_OUT can be adjusted by the frequency option signals FREQ[0:1] and FREQ_B[0:1], where the frequency option signal FREQ_B[0:1] is inverse to the frequency option signals FREQ[0:1]. For example, when the frequency option signals FREQ[0:1] and FREQ_B[0:1] are set to 2'b00 and 2'b11, respectively, the P-type transistors within the frequency calibration circuits 113U and 123U and the N-type transistors within the frequency calibration circuits 113L and 123L are turned on, improving the driving capabilities of transistor FP1 and transistor FN1. As a result, the operating frequency range of the input clock signal CK_IN can be extended, indicating that the input clock signal CK_IN can operate at a higher operating frequency. When the frequency option signals FREQ[0:1] and FREQ_B[0:1] are set to 2'b11 and 2'b00, respectively, the frequency calibrating function of the duty cycle correction circuit is disabled.

FIG. 2C is a schematic diagram of a duty cycle correction circuit in accordance with some embodiments of the present disclosure.

In some embodiments, the duty cycle correction circuit 100B shown in FIG. 2C similar to the duty cycle correction circuit 100A shown in FIG. 2B, with the difference being that the portions in the trimming code EN or ENB provided to the trimming circuits 112BU, 112BL, 122BU, and 122BL are different from those in FIG. 2B. For example, the first portion of the trimming code EN provided to the trimming circuit 112BU includes even-number indexed bits of the trimming code EN, such as EN[0], EN[2], . . . , and EN[62]. The second portion of the trimming code EN provided to the trimming circuit 112BL includes odd-number indexed bits, such as EN[1], EN[3], . . . , and EN[63]. The first portion of the trimming code ENB provided to the trimming circuit 122BU includes odd-number indexed bits of the trimming code ENB, such as ENB[1], ENB[3], . . . , and ENB[63]. The second portion of the trimming code ENB provided to the trimming circuit 122BL includes even-number indexed bits of the trimming code ENB, such as ENB[0], ENB[2], . . . , and ENB[62]. With the balanced circuit design, the duty cycle correction circuit 100B shown in FIG. 2C is capable of balancing the duty cycle of the output clock signal CK_OUT in a manner similar to the duty cycle correction circuit 100A shown in FIG. 2B.

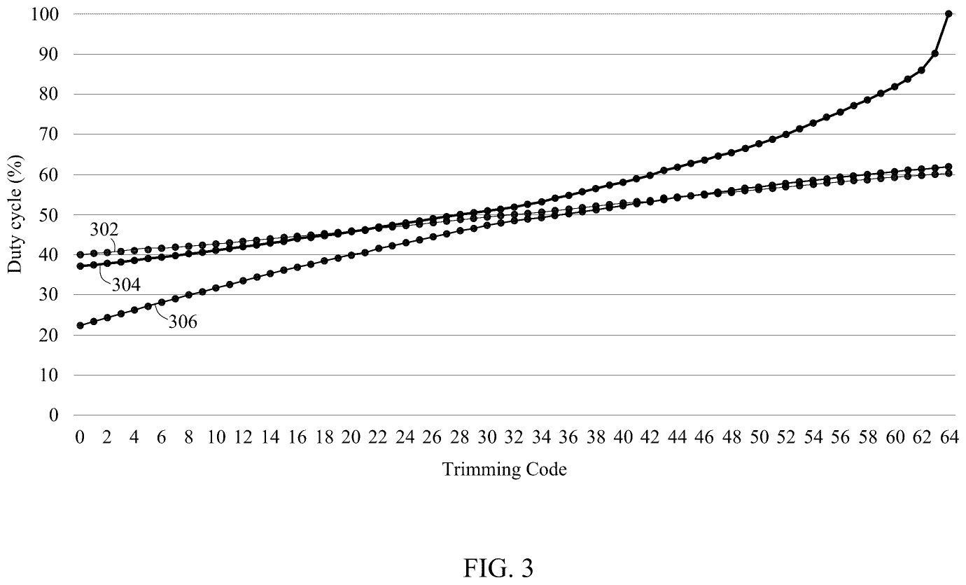

FIG. 3 is a diagram illustrating the relationship between the trimming code and the duty cycle of the output clock signal in different process corner cases in accordance with the embodiment of FIGS. 2A-2B.

In some embodiments, as depicted in FIG. 3, curves 302, 304, and 306 refers to the duty cycle with respect to the trimming code in TC (typical case) case, FSLL (fast-slow) edge corner case, and SFLL (slow-fast) edge corner case. For example, due to manufacturing variations, both N-type and P-type MOS transistors in different wafers have different driving capabilities or different operational currents. A transistor is called “fast” (“F”) if the transistor has a driving capability higher than that of a normal or an average transistor. In contrast, a transistor is “slow” (“S”) if the transistor has a driving capability lower than that of an average transistor. The TC case may indicate that the driving capability of a P-type transistor is substantially equal to that of an N-type transistor. The FSLL edge corner case may indicate that the driving capability of an N-type transistor is much higher than that of a P-type transistor (i.e., relatively fast NMOS and relatively slow PMOS). The SFLL edge corner case may indicate that the driving capability of an N-type transistor is much lower than that of a P-type transistor (i.e., relatively slow NMOS and relatively fast PMOS). As can be seen from FIG. 3, the duty cycle of the output clock signal CK_OUT can be adjusted gradually by per trimming code in a linear manner. With an appropriate designated trimming code, the duty cycle correction circuit 100A can generate the output clock signal CK_OUT with the duty cycle of substantially 50%. In some embodiments, when the driving capability of P-type transistors is different from that of N-type transistors within the same integrated circuit, a PN mismatch condition occurs.

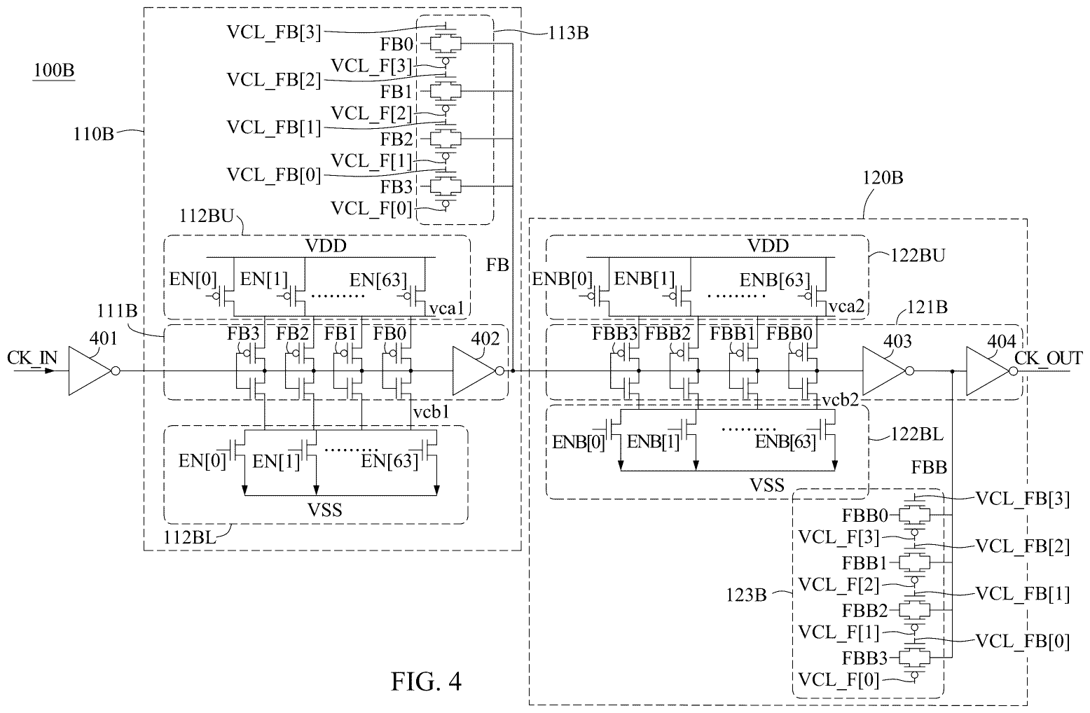

FIG. 4 is a schematic diagram of a duty cycle correction circuit in accordance with some embodiments of the present disclosure.

In some embodiments, the duty cycle correction circuit 100B includes a master circuit 110B and a slave circuit 120B. The master circuit 110B includes a master compensation circuit 111B, trimming circuits 112BU and 112BL, and a frequency calibration circuit 113B, while the slave circuit 120B includes a slave compensation circuit 121B, trimming circuits 122BU and 122BL, and a frequency calibration circuit 123B.

In some embodiments, the master compensation circuit 111B includes four inverters and an inverter 402 connected in series. The input terminals of the four inverters within the master compensation circuit 111B receives feedback signals FB3, FB2, FB1, and FB0 generated by the frequency calibration circuit 113B, respectively. Additionally, the output terminals of the four inverters within the master compensation circuit 111B are connected to the input terminal of the inverter 402.

In some embodiments, the trimming circuit 112BU is coupled between the power supply voltage VDD and the master compensation circuit 111B, while the trimming circuit 112BL is coupled between the reference voltage VSS and the master compensation circuit 111B. The trimming circuit 112BU includes a plurality of P-type transistors, each receiving a respective bit of the trimming code EN[0:63]. The trimming circuit 112BL includes a plurality of N-type transistors, each receiving a respective bit of the trimming code EN[0:63]. The trimming circuits 112BU and 112BL can provide voltages vca1 and vcb1 at first terminals and second terminals of the four inverters within the master compensation circuit 111B.

In some embodiments, the slave compensation circuit 121B includes four inverters and an inverter 403 connected in series. The input terminals of the four inverters within the slave compensation circuit 121B receives feedback signals FBB3, FBB2, FBB1, and FBB0 generated by the frequency calibration circuit 123B, respectively. Additionally, the output terminals of the four inverters within the slave compensation circuit 121B are connected to the input terminal of the inverter 403.

In some embodiments, the trimming circuit 122BU is coupled between the power supply voltage VDD and the slave compensation circuit 121B, while the trimming circuit 122BL is coupled between the reference voltage VSS and the slave compensation circuit 121B. The trimming circuit 122BU includes a plurality of P-type transistors, each receiving a respective bit of the trimming code ENB[0:63]. The trimming circuit 122BL includes a plurality of N-type transistors, each receiving a respective bit of the trimming code ENB[0:63]. The trimming circuits 122BU and 122BL can provide voltages vca2 and vcb2 at first terminals and second terminals of the four inverters within the slave compensation circuit 121B.

In some embodiments, frequency calibration circuit 113B includes a plurality of transmission gates, each including a P-type transistor and an N-type transistor, as depicted in FIG. 4. For example, each transmission gate is controlled by a respective frequency option signal pair VCL_F[n] and VCL_FB[n], where n is an integer from 0 to 3. Specifically, the intermediate clock signal FB generated by the inverter 402 is provided to each transmission gate within the frequency calibration circuit 113B. When then frequency option signal VCL_F[3]=0 and VCL_FB[3]=1, the topmost transmission gate within the frequency calibration circuit 113B is activated, and the feedback signal is FB0 is generated and provided to the input terminal of the respective inverter within the master compensation circuit 111B. Other feedback signals FB1 to FB3 can be generated in a similar manner.

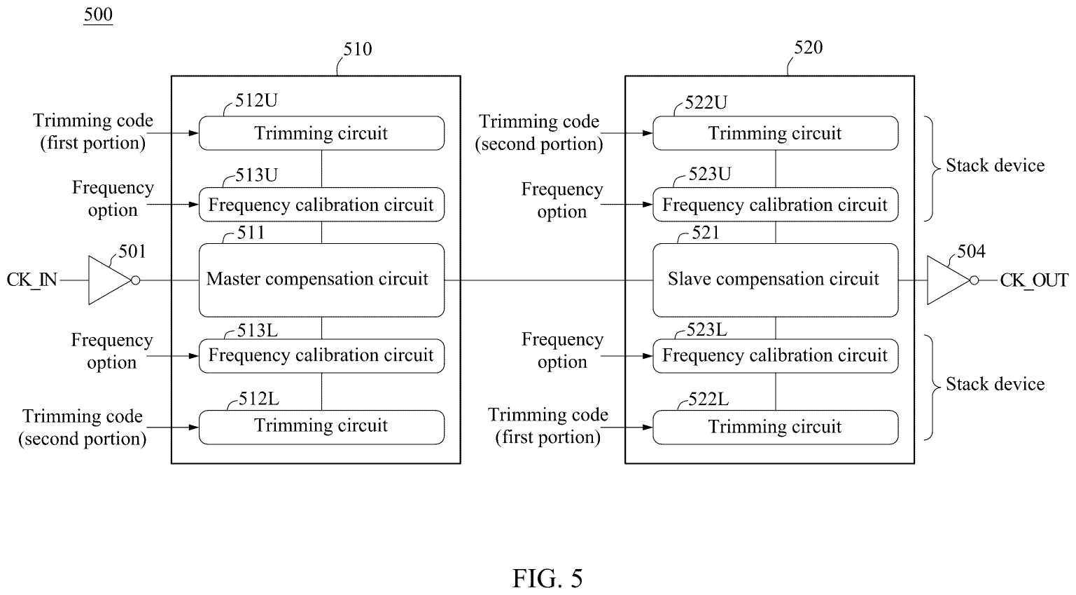

In some embodiments, frequency calibration circuit 123B includes a plurality of transmission gates, each including a P-type transistor and an N-type transistor, as depicted in FIG. 4. For example, each transmission gate is controlled by a respective frequency option signal pair VCL_F[n] and VCL_FB[n], where n is an integer from 0 to 3. Specifically, the intermediate clock signal FBB generated by the inverter 403 is provided to each transmission gate within the frequency calibration circuit 123B. When then frequency option signal VCL_F[3]=0 and VCL_FB[3]=1, the topmost transmission gate within the frequency calibration circuit 123B is activated, and the feedback signal is FBB0 is generated and provided to the input terminal of the respective inverter within the master compensation circuit 111B. Other feedback signals FBB1 to FBB3 can be generated in a similar manner. Since more P-type switches and N-type switches are used in the trimming circuits 112BU, 112BL, 122BU, and 122BL, the duty cycle correction circuit 100B shown in FIG. 5 can further suppress the noise of the power supply voltage VDD.

FIG. 5 is a block diagram of a duty cycle correction circuit in accordance with some embodiments of the present disclosure.

In some embodiments, the duty cycle correction circuit 500 includes a master circuit 510 and a slave circuit 520. The master circuit 510 includes a master compensation circuit 511, trimming circuits 512U and 512L, and frequency calibration circuits 513U and 513L. The trimming circuits 512U and 512L are coupled to the master compensation circuit 511 through the frequency calibration circuits 513U and 513L, respectively. Additionally, the trimming circuit 512U and the frequency calibration circuit 513U may form a stack device, while the trimming circuit 512L and frequency calibration circuit 513L may form another stack device.

In some embodiments, the slave circuit 520 includes a slave compensation circuit 511, trimming circuits 522U and 522L, and frequency calibration circuits 523U and 523L. The trimming circuits 522U and 522L are coupled to the slave compensation circuit 521 through the frequency calibration circuits 523U and 523L, respectively. Additionally, the trimming circuit 522U and the frequency calibration circuit 523U may form a stack device, while the trimming circuit 522L and frequency calibration circuit 523L may form another stack device.

In some embodiments, a first portion and a second portion of the trimming code EN are provided to the trimming circuits 512U and 512L, respectively. Additionally, frequency option signals FREQ and FREQ_B are provided to the frequency calibration circuits 513U and 513L. A second portion and a first portion of the trimming code ENB are provided to the trimming circuits 522U and 522L, respectively. Additionally, frequency option signals FREQ and FREQ_B are provided to the frequency calibration circuits 523U and 523L.

It should be noted that the duty cycle correction circuit 500 shown in FIG. 5 has a balanced circuit design similar to the duty cycle correction circuit 100A shown in FIG. 2B, with the difference being that the trimming circuits and frequency calibration circuits form respective stack devices in the duty cycle correction circuit 500.

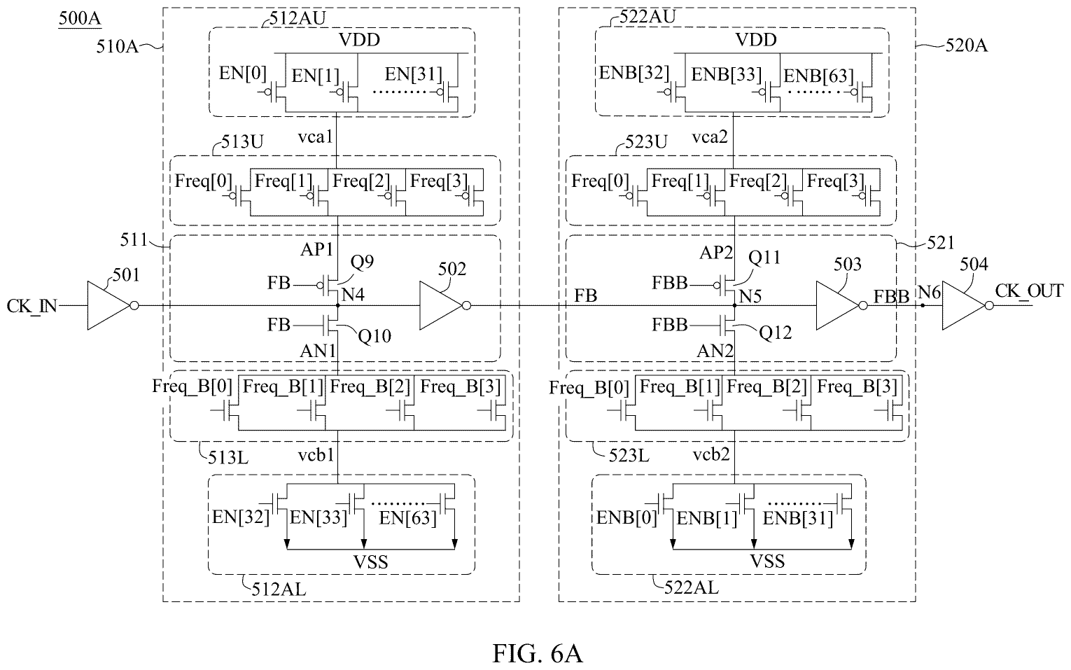

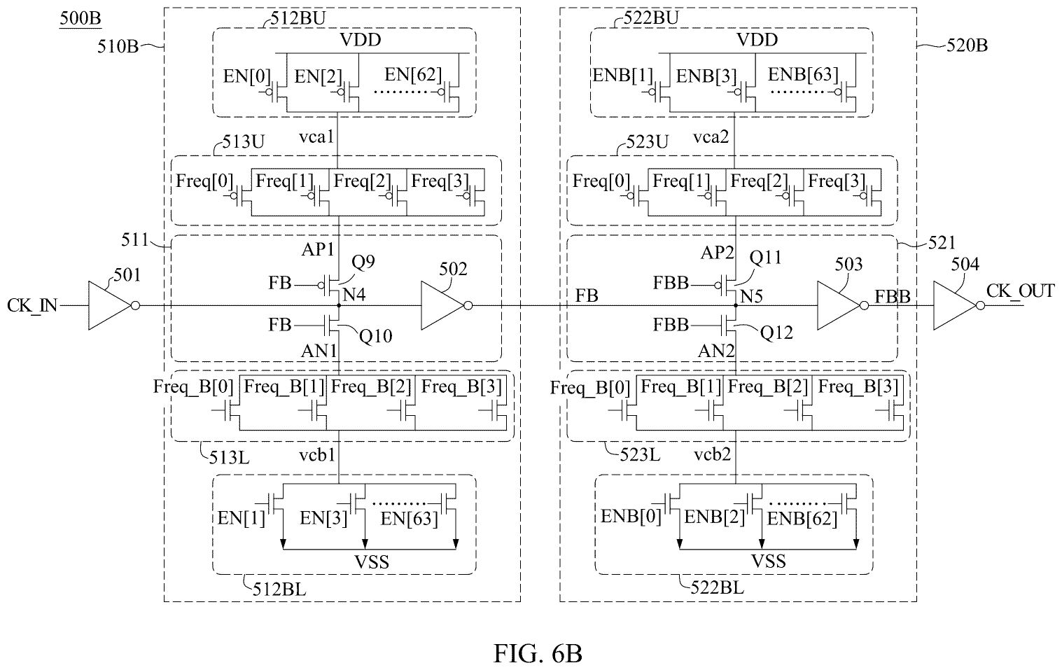

FIG. 6A is a schematic diagram of a duty cycle correction circuit in accordance with some embodiments of the present disclosure.

In some embodiments, the duty cycle correction circuit 500 shown in FIG. 5 can be implemented using the duty cycle correction circuit 500A shown in FIG. 6A. The input clock signal CK_IN is provided to node N4 of the master compensation circuit 511 through inverter 501. The master compensation circuit 511 includes transistors Q9 and Q10 and an inverter 502. The intermediate clock signal generated by the inverter 502 is fed back to the gate terminals of transistors Q9 and Q10.

In some embodiments, the first portion and the second portion of the trimming code EN may refer to the least significant half and the most significant half of the trimming code EN[0:63], such as EN[0:31] and EN[32:63], respectively. The trimming circuit 512AU provides a voltage vca1 to the frequency calibration circuit 513U depending on the first portion of the trimming code EN (e.g., EN[0:31]), and the frequency calibration circuit 513U, which receives the frequency option signal Freq[0:3], provides a voltage AP1 to the source terminal of transistor Q9. Additionally, the trimming circuit 512AL provides a voltage vcb1 to the frequency calibration circuit 513L depending on the second portion of the trimming code EN (e.g., EN[32:63]), and the frequency calibration circuit 513L, which receives the frequency option signal Freq_B[0:3], provides a voltage AN1 to the source terminal of transistor Q10.

In some embodiments, the intermediate clock signal FB generated by the inverter 502 is provided to node N5 of the slave compensation circuit 521. The slave compensation circuit 521 includes transistors Q11 and Q12 and an inverter 503. The inverter 503 converts the feedback signal FB to another feedback signal FBB at node N6, which is fed back to the gate terminals of transistors Q11 and Q12. The feedback signal FBB pass through inverter 504 to obtain the output clock signal CK_OUT.

In some embodiments, the first portion and the second portion of the trimming code ENB may refer to the least significant half and the most significant half of the trimming code EN[0:63], such as EN[0:31] and EN[32:63], respectively. The trimming circuit 522AU provides a voltage vca2 to the frequency calibration circuit 523U depending on the second portion of the trimming code ENB (e.g., ENB[32:63]), and the frequency calibration circuit 523U, which receives the frequency option signal Freq[0:3], provides a voltage AP2 to the source terminal of transistor Q11. Additionally, the trimming circuit 522AL provides a voltage vcb2 to the frequency calibration circuit 523L depending on the first portion of the trimming code ENB (e.g., ENB[0:31]), and the frequency calibration circuit 523L, which receives the frequency option signal Freq_B[0:3], provides a voltage AN2 to the source terminal of transistor Q12.

FIG. 6B is a schematic diagram of a duty cycle correction circuit in accordance with some embodiments of the present disclosure.

The duty cycle correction circuit 500B shown in FIG. 6B is similar to the duty cycle correction circuit 500A shown in FIG. 6A, with the difference being that the first portion and second portion of the trimming code EN provided to the trimming circuits 512BU and 512BL refer to the even-number indexed bits (e.g., EN[0], EN[2], . . . , and EN[62]) and odd-number indexed bits (e.g., EN[1], EN[3], . . . , and EN[63]) of the trimming code EN[0:63], respectively, indicating that the control signals for the P-type transistors and N-type transistors within the trimming circuits 512BU, 512BL, 522BU, and 522BL can be allocated loosely for layout placement, resulting in a lower parasitic loading of layout routing.

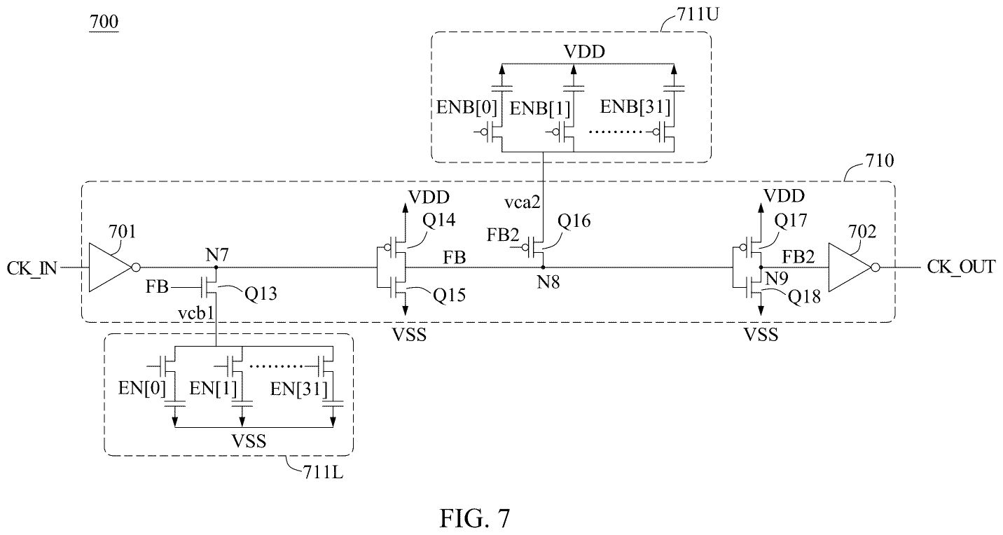

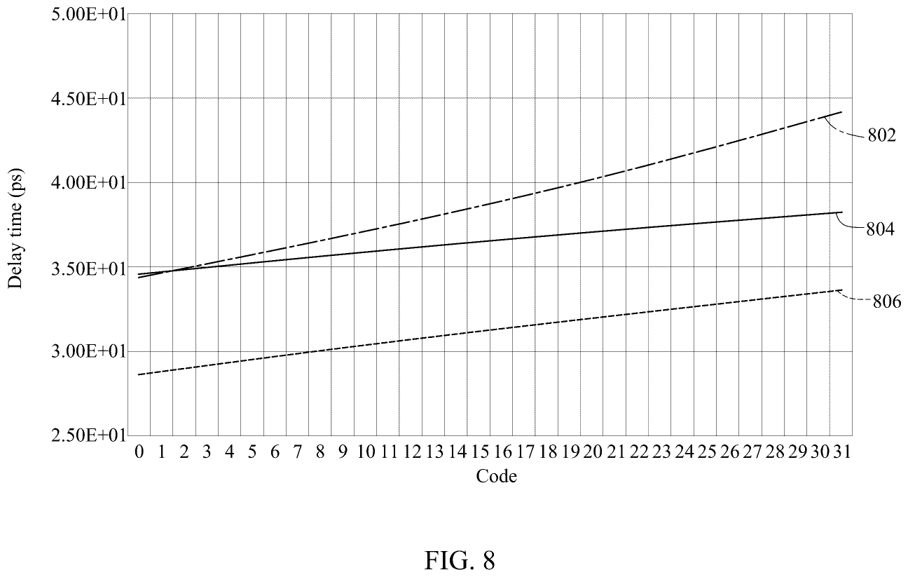

FIG. 7 is a schematic diagram of digitally controlled delay line (DCDL) circuit in accordance with some embodiments of the present disclosure. FIG. 8 is a diagram illustrating the relationship between a delay time of the output clock signal with respect to the trimming code (e.g., “Code”) in different corner cases in accordance with the embodiment of FIG. 7.

In some embodiments, the DCDL circuit 700 shown in FIG. 7 may also be regarded as a phase trimming circuit. The DCDL circuit 700 includes a compensation circuit 710 and trimming circuits 711U and 711L. The compensation circuit 710 includes an inverter 701 and transistors Q13 to Q18. The input clock signal CK_IN is provided to node N7 through inverter 701. Transistors Q14 and Q15 form an inverter, while transistors Q17 and Q18 form another inverter. The intermediate clock signal FB generated by the inverter including transistors Q14 and Q15 at node N8 is provided to the gate terminal of transistor Q13. A feedback clock signal FB2 is generated at node N9, which is fed back to the gate terminal of transistor Q16. The feedback clock signal FB2 passes through inverter 702 to obtain the output clock signal CK_OUT.

In some embodiments, the trimming circuit 711U includes a plurality of P-type transistors, each receiving a respective bit of the trimming code ENB[0:31]. Additionally, each P-type transistor within the trimming circuit 711U is coupled to the power supply voltage VDD through a respective capacitor. The trimming circuit 711U provides a voltage signal vca2 to the source terminal of transistor Q16. In some embodiments, each P-type transistor within the trimming circuit 711U is coupled to the power supply voltage VDD through a respective resistor.

In some embodiments, the trimming circuit 711L includes a plurality of N-type transistors, each receiving a respective bit of the trimming code EN[0:31]. Additionally, each N-type transistor within the trimming circuit 711L is coupled to the reference voltage VSS through a respective capacitor. The trimming circuit 711L provides a voltage signal vcb1 to the source terminal of transistor Q13. In some embodiments, each N-type transistor within the trimming circuit 711L is coupled to the reference voltage VSS through a respective resistor.

Specifically, the overall loading for the voltage pull-up duration and the voltage pull-down duration can be controlled by the trimming codes EN and ENB. For example, when a particular bit of the trimming code EN is “1”, the corresponding N-type transistor within the trimming circuit 711L is activated to increase the loading for the voltage pull-down duration. Similarly, when the particular bit of the trimming code ENB is “0”, the corresponding P-type transistor within the trimming circuit 711U is activated to increase the loading for the voltage pull-up duration. On the contrary, when a particular bit of the trimming code EN is “0”, the corresponding N-type transistor within the trimming circuit 711L is deactivated, and thus the respective loading (e.g., capacitor) is cut off from transistor Q13 for the voltage pull-down duration. Similarly, when the particular bit of the trimming code ENB is “1”, the corresponding P-type transistor within the trimming circuit 711U is deactivated, and thus the respective loading (e.g., capacitor) is cut off from transistor Q16 for the voltage pull-up duration. Accordingly, the delay time of the output clock signal CK_OUT can be adjusted with an appropriate design of the trimming code EN and ENB.

For example, as depicted in FIG. 8, curves 806, 804, and 802 refer to the relationship of the delay time of the output clock signal CK_OUT with respect to the trimming code (i.e., “Code”) for the TC, FSLL, and SFLL corner cases. With the balance circuit design of the DCDL circuit 700 shown in FIG. 7, high linearity of curves 806, 804, and 802 can be achieved.

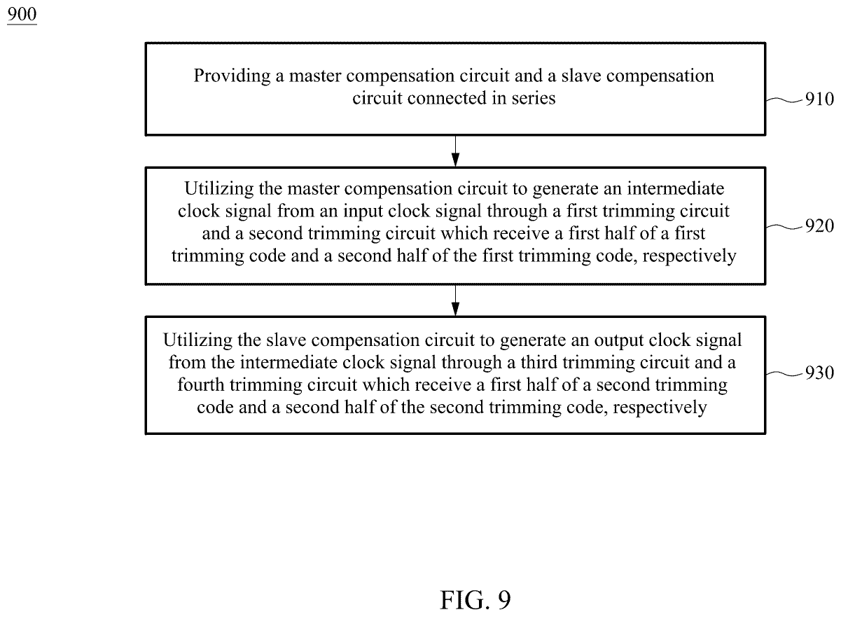

FIG. 9 is a flowchart of a method for operating a duty cycle correction circuit in accordance with some embodiments of the present disclosure. Please refer to both FIG. 2B and FIG. 9.

At operation 910, a master compensation circuit and a slave compensation circuit connected in series are provided. In some embodiments, the master compensation 111 and the slave compensation 121 are connected in series to compensate the duty cycle imbalance caused by mismatching of the P-type and N-type transistors.

At operation 920, utilizing the master compensation circuit to generate an intermediate clock signal from an input clock signal through a first trimming circuit and a second trimming circuit which receive a first half of a first trimming code and a second half of the first trimming code, respectively.

At operation 930, utilizing the slave compensation circuit to generate an output clock signal from the intermediate clock signal through a third trimming circuit and a fourth trimming circuit which receive a first half of a second trimming code and a second half of the second trimming code, respectively. In some embodiments, the first half of the trimming code EN may refer to the least significant half or the lower half (e.g., EN[0:31]), while the second half of the trimming code EN may refer to the most significant half or the upper half (e.g., EN[32:63]). Similarly, the first half of the trimming code ENB may refer to the least significant half (e.g., ENB[0:31]), while the second half of the trimming code ENB may refer to the most significant half (e.g., ENB[32:63]). In some other embodiments, the first half of the trimming code EN may refer to the most significant half or the upper half (e.g., EN[32:63]), while the second half of the trimming code EN may refer to the least significant half or the lower half (e.g., EN[0:31]). Similarly, the first half of the trimming code ENB may refer to the most significant half (e.g., ENB[32:63]), while the second half of the trimming code ENB may refer to the least significant half (e.g., ENB[0:31]). In still some other embodiments, the first half of the trimming code EN may refer to even number indexed bits (e.g., EN[0], EN[2], . . . , EN[62]), while the second half of the trimming code EN may refer to the odd number indexed bits (e.g., EN[1], EN[3], . . . , EN[63]). Similarly, the first half of the trimming code ENB may refer to even number indexed bits (e.g., ENB[0], ENB[2], . . . , ENB[62]), while the second half of the trimming code ENB may refer to the odd number indexed bits (e.g., ENB[1], ENB[3], . . . , ENB[63]).

An aspect of the present disclosure provides an integrated circuit which includes a master circuit and a slave circuit. The master circuit is configured to receive an input clock signal and generate an intermediate clock signal based on a first half and a second half of a first trimming code. The slave circuit is electrically connected to the master circuit and is configured to receive the intermediate clock signal and generate an output clock signal from the intermediate clock signal based on a first half and a second half of a second trimming code. The first trimming code is complementary to the second trimming code.

Another aspect of the present disclosure provides an integrated circuit which includes a master circuit and a slave circuit. The master circuit is configured to receive an input clock signal and generate an intermediate clock signal based on a first trimming code. The slave circuit is electrically connected to the master circuit and is configured to receive the intermediate clock signal and generate an output clock signal from the intermediate clock signal based on a second trimming code complementary to the first trimming code.

Yet another aspect of the present disclosure a method. The method includes the following steps: providing a master compensation circuit and a slave compensation circuit connected in series; utilizing the master compensation circuit to generate an intermediate clock signal from an input clock signal through a first trimming circuit and a second trimming circuit which receive a first half of a first trimming code and a second half of the first trimming code, respectively; and utilizing the slave compensation circuit to generate an output clock signal from the intermediate clock signal through a third trimming circuit and a fourth trimming circuit which receive a first half of a second trimming code and a second half of the second trimming code, respectively. The second trimming code is complementary to the first trimming code.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. An integrated circuit, comprising:
a master circuit, configured to receive an input clock signal and generate an intermediate clock signal based on a first half and a second half of a first trimming code; and
a slave circuit, electrically connected to the master circuit, and configured to receive the intermediate clock signal and generate an output clock signal from the intermediate clock signal based on a first half and a second half of a second trimming code,
wherein the first trimming code is complementary to the second trimming code.

2. The integrated circuit of claim 1, wherein the master circuit comprises:
a first trimming circuit, configured to receive the first half of the first trimming code to provide a first voltage;
a second trimming circuit, configured to receive the second half of the first trimming code to provide a second voltage; and
a master compensation circuit, configured to receive the input clock signal and generate the intermediate clock signal from the input clock signal based on the first voltage and the second voltage.

3. The integrated circuit of claim 2, wherein:
the first trimming circuit comprises a plurality of P-type transistors, each receiving a respective bit of the first half of the first trimming code; and
the second trimming circuit comprises a plurality of N-type transistors, each receiving a respective bit of the second half of the first trimming code.

4. The integrated circuit of claim 2, wherein the master compensation circuit comprises:
a first inverter, configured to convert the input clock signal to generate a first clock signal at a first node;
a first transistor, having a gate terminal receiving the intermediate clock signal, a first terminal receiving the first voltage, and a second terminal coupled to the first node; and
a second transistor, having a gate terminal receiving the intermediate clock signal, a first terminal coupled to the first node, and a second terminal receiving the second voltage.

5. The integrated circuit of claim 4, wherein the master compensation circuit further comprises:
a first frequency calibration circuit, configured to receive a first frequency option signal to generate a third voltage;
a second frequency calibration circuit, configured to receive a second frequency option signal complementary to the first frequency option signal to generate a fourth voltage;
a third transistor, having a gate terminal receiving the first clock signal, a first terminal receiving the third voltage, and a second terminal coupled to a second node; and
a fourth transistor, having a gate terminal receiving the first clock signal, a first terminal coupled to the second node, and a second terminal receiving the fourth voltage,
wherein the master compensation circuit generates the intermediate clock signal at the second node.

6. The integrated circuit of claim 5, wherein:
the first frequency calibration circuit comprises a plurality of P-type transistors, each receiving a respective bit of the first frequency option signal; and
the second frequency calibration circuit comprises a plurality of N-type transistor, each receiving a respective bit of the second frequency option signal.

7. The integrated circuit of claim 5, wherein the slave circuit comprises:
a third trimming circuit, configured to receive the second half of the second trimming code to provide a fifth voltage;
a fourth trimming circuit, configured to receive the first half of the second trimming code to provide a sixth voltage; and
a slave compensation circuit, configured to receive the intermediate clock signal at the second node and generate the output clock signal from the intermediate clock signal based on the fifth voltage and the sixth voltage.

8. The integrated circuit of claim 7, wherein:
the third trimming circuit comprises a plurality of P-type transistors, each receiving a respective bit of the second half of the second trimming code; and
the fourth trimming circuit comprises a plurality of N-type transistors, each receiving a respective bit of the first half of the second trimming code.

9. The integrated circuit of claim 7, wherein the slave compensation circuit comprises:
a fifth transistor, having a gate terminal receiving a feedback clock signal, a first terminal receiving the fifth voltage, and a second terminal coupled to the second node; and
a sixth transistor, having a gate terminal receiving the feedback clock signal, a first terminal coupled to the second node, and a second terminal receiving the sixth voltage.

10. The integrated circuit of claim 9, wherein the slave compensation circuit further comprises:
a third frequency calibration circuit, configured to receive the first frequency option signal to generate a seventh voltage;
a fourth frequency calibration circuit, configured to receive the second frequency option signal to generate an eighth voltage;
a seventh transistor, having a gate terminal receiving the intermediate clock signal, a first terminal receiving the seventh voltage, and a second terminal coupled to a third node;
an eighth transistor, having a gate terminal receiving the intermediate clock signal, a first terminal coupled to the third node, and a second terminal receiving the eighth voltage; and
a second inverter, configured to convert the feedback clock signal generated at the third node to generate the output clock signal.

11. The integrated circuit of claim 1, wherein the first half and the second half of the first trimming code refers to an upper half and a lower half of the first trimming code, respectively.

12. The integrated circuit of claim 1, wherein the first half and the second half of the first trimming code refers to a lower half and an upper half of the first trimming code, respectively.

13. The integrated circuit of claim 1, wherein the first half and the second half of the first trimming code refers to even-number indexed bits and odd-number indexed bits of the first trimming code, respectively.

14. The integrated circuit of claim 5, wherein:
the first trimming circuit receives a power supply voltage and is coupled to the first transistor;
the second trimming circuit receives a reference voltage and is coupled to the second transistor;
the first frequency calibration circuit receives the power supply voltage and is coupled to the third transistor; and
the second frequency calibration circuit receives the reference voltage and is coupled to the fourth transistor.

15. The integrated circuit of claim 5, wherein:
the first trimming circuit receives a power supply voltage and is coupled to the master compensation circuit through the first frequency calibration circuit; and
the second trimming circuit receives a reference voltage and is coupled to the master compensation circuit through the second frequency calibration circuit.

16. An integrated circuit, comprising:
a master circuit, configured to receive an input clock signal and generate an intermediate clock signal based on a first trimming code; and
a slave circuit, electrically connected to the master circuit, and configured to receive the intermediate clock signal and generate an output clock signal from the intermediate clock signal based on a second trimming code complementary to the first trimming code.

17. The integrated circuit of claim 16, wherein the master circuit comprises:
a first frequency calibration circuit, comprising a plurality of transmission gates, each receiving the intermediate clock signal and respective frequency option signals to generate a respective first feedback signal;
a master compensation circuit, comprising a plurality of first inverters connected in series, each first inverter receiving the respective first feedback signal from each transmission gate within the first frequency calibration circuit;
a first trimming circuit, receiving a power supply voltage, the first trimming circuit comprising a plurality of P-type transistors, each receiving a respective bit of the first trimming code to provide a first voltage to the respective first inverter of the master compensation circuit; and
a second trimming circuit, receiving a reference voltage, the second trimming circuit comprising a plurality of N-type transistors, each receiving the respective bit of the first trimming code to provide a second voltage to the respective first inverter of the master compensation circuit.

18. The integrated circuit of claim 17, wherein the slave circuit comprises:
a second frequency calibration circuit, comprising a plurality of transmission gates, each receiving the output clock signal and the respective frequency option signals to generate a respective second feedback signal;
a slave compensation circuit, comprising a plurality of second inverters connected in series, each second inverter receiving the respective second feedback signal from each transmission gate within the first frequency calibration circuit;
a third trimming circuit, receiving the power supply voltage, the third trimming circuit comprising a plurality of P-type transistors, each receiving a respective bit of the second trimming code to provide a third voltage to the respective second inverter of the slave compensation circuit; and
a fourth trimming circuit, receiving the reference voltage, the fourth trimming circuit comprising a plurality of N-type transistors, each receiving the respective bit of the second trimming code to provide a fourth voltage to the respective second inverter of the slave compensation circuit.

19. A method, comprising:
providing a master compensation circuit and a slave compensation circuit connected in series;
utilizing the master compensation circuit to generate an intermediate clock signal from an input clock signal through a first trimming circuit and a second trimming circuit which receive a first half of a first trimming code and a second half of the first trimming code, respectively; and
utilizing the slave compensation circuit to generate an output clock signal from the intermediate clock signal through a third trimming circuit and a fourth trimming circuit which receive a first half of a second trimming code and a second half of the second trimming code, respectively, wherein the second trimming code is complementary to the first trimming code.

20. The method of claim 19, wherein:
the first half and the second half of the first trimming code comprise a lower half and an upper half of the first trimming code, respectively; and
the first half and the second half of the second trimming code comprise an upper half and a lower half of the second trimming code, respectively.
